(19) United States
(12) Patent Application Publication
(10) Pub. No.: US 2026/0201276 A1
(43) Pub. Date: Jul. 16, 2026

(54) CLEANING COMPOSITION AND METHOD OF FABRICATING SEMICONDUCTOR DEVICE USING THE SAME

(71) Applicant: DONGWOO FINE-CHEM CO., LTD., Jeollabuk-do (KR)

(72) Inventors: JONG WOOK BAEK, Jeollabuk-do (KR); GI WOO LEE, Jeollabuk-do (KR); DONG GYU LEE, Jeollabuk-do (KR)

(21) Appl. No.: 19/367,955

(22) Filed: Oct. 24, 2025

(30) Foreign Application Priority Data
Nov. 1, 2024 (KR) 10-2024-0153257

(51) Int. Cl. C11D 3/24; C11D 3/04; C11D 3/20

(52) U.S. Cl. CPC C11D 3/245; C11D 3/042; C11D 3/2082; C11D 2111/22

(57) ABSTRACT

A cleaning composition includes a cyclic amide-based compound, a polar aprotic solvent, and a fluorine-based compound. The cleaning composition can rapidly remove a silicon-based polymer without generating residue and etching a metal layer. The cleaning composition can be used for a cleaning process of a wafer in a fabrication of a semiconductor device.

### CROSS REFERENCE TO RELATED APPLICATION AND CLAIM OF PRIORITY

This application claims priority to Korean Patent Application No. 10-2024-0153257 filed on Nov. 1, 2024 in the Korean Intellectual Property Office, the entire disclosure of which is incorporated herein by reference for all purposes.

### BACKGROUND

### 1. Field

The present invention relates to a cleaning composition and a method of fabricating a semiconductor device using the same.

### 2. Description of the Related Art

To form wirings or insulating patterns included in a highly integrated semiconductor device, a mask pattern may be formed by coating and curing a photoresist on an etching object layer. After performing a dry etching process using the mask pattern, the mask pattern may be removed by, e.g., an ashing process.

During the dry etching and/or the ashing process, a photoresist material may be transformed, and the transformed photoresist may remain on the wirings, an insulating layer, or the semiconductor substrate. To remove the residual transformed photoresist, a wet process using a cleaning composition may be utilized.

However, the cleaning composition may damage a wiring material containing a conductive metal, or the insulating layer containing an organic material or a silicon-based inorganic material.

When using conventional cleaning compositions, the wiring containing a metal such as ruthenium is also removed, or a residual photoresist was not sufficiently dissolved. Thus, improvement of a selectivity is required in the cleaning compositions.

### SUMMARY

According to an aspect of the present invention, there is provided a cleaning composition having enhanced cleaning capability.

According to an aspect of the present invention, there is provided a method of fabricating a semiconductor device using the cleaning composition.
(1) A cleaning composition, including: a fluorine-based compound; an organic acid salt compound; an inorganic acid compound; and water, wherein a content of water is at least 50 wt % based on a total weight of the composition, and the cleaning composition has a pH of 0.5 to 4.
(2) The cleaning composition of the above (1), wherein the cleaning composition has a pH of 1 to 3.
(3) The cleaning composition of the above (1), wherein the fluorine-based compound includes an ionic bond between a hydrogen cation or an ammonium cation, and a fluorine anion.
(4) The cleaning composition of the above (3), wherein the ammonium cation contains 4 to 20 carbon atoms.
(5) The cleaning composition of the above (1), wherein a content of the fluorine-based compound is in a range from 0.005 wt % to 10 wt % based on the total weight of the cleaning composition.
(6) The cleaning composition of the above (1), wherein the organic acid salt compound includes an ionic bond between an ammonium cation and an organic acid-derived anion.
(7) The cleaning composition of the above (6), wherein the organic acid includes at least one selected from the group consisting of formic acid, acetic acid, propionic acid, butyric acid, palmitic acid, stearic acid, oleic acid, oxalic acid, malonic acid, succinic acid, tartaric acid, maleic acid, glycolic acid, glutaric acid, adipic acid, sulfosuccinic acid, valeric acid, caproic acid, caprylic acid, capric acid, lauric acid, myristic acid, lactic acid, malic acid, citric acid, tartaric acid, benzoic acid, salicylic acid, paratoluenesulfonic acid, naphthoic acid, nicotinic acid, toluic acid, anisic acid, cumic acid and phthalic acid.
(8) The cleaning composition of the above (1), wherein a content of the organic acid salt compound is in a range from 0.01 wt % to 10 wt % based on the total weight of the composition.
(9) The cleaning composition of the above (1), wherein the inorganic acid compound includes at least one selected from the group consisting of hydrochloric acid, phosphoric acid, sulfuric acid and boric acid.
(10) The cleaning composition of the above (1), wherein the inorganic acid compound includes a compound having a redox potential of 650 mV or less, or a salt thereof.
(11) The cleaning composition of the above (1), wherein a content of water is 80 wt % or more based on the total weight of the composition.
(12) The cleaning composition of the above (1), wherein the cleaning composition does not include an amine compound, an ammonium hydroxide compound, a metal hydroxide, a peroxide compound, an organic solvent, or a surfactant.
(13) A method for fabricating a semiconductor device, including: forming a photoresist pattern on a substrate; removing the photoresist pattern after an etching process using the photoresist pattern; and cleaning a residue from the photoresist pattern using the cleaning composition according to the above embodiments.

The cleaning composition according to example embodiments of the present invention may have a high cleaning capability with respect to a photoresist residue transformed by a high energy process. Accordingly, a high-quality semiconductor device may be provided.

Additionally, the cleaning composition may not etch a wiring including a metal such as Mo, W, Ru, or the like, and a layer such as a silicon oxide layer and a silicon nitride layer. Accordingly, the transformed photoresist residue may be selectively removed by using the highly selective cleaning composition.

According to a method of fabricating a semiconductor device according to example embodiments of the present invention, a high-quality semiconductor device with a reduced amount of the transformed photoresist may be provided.

### BRIEF DESCRIPTION OF THE DRAWINGS

FIGS. 1 to 5 are schematic cross-sectional views illustrating a method of fabricating a semiconductor device in accordance with example embodiments.

### DETAILED DESCRIPTION OF THE EMBODIMENTS

Embodiments of the present invention provide a cleaning composition including a fluorine-based compound, an organic acid salt compound, an inorganic acid compound, and water. Embodiments of the present invention also provide a method of fabricating a semiconductor device using the cleaning composition.

Hereinafter, embodiments of the present invention will be described in detail.

A cleaning composition (hereinafter, that may be referred to as a composition) according to embodiments includes a fluorine-based compound, an organic acid salt compound, an inorganic acid compound, and water.

The fluorine-based compound may be a main component for removing a transformed photoresist residue. The transformed photoresist residue may be generated by a dry etching process or a photoresist ashing process.

The dry etching process or the ashing process may be performed using a high energy source such as a high-temperature heating and a high-energy density light irradiation. Accordingly, a photoresist may be removed or transformed. The transformed photoresist may not be removed and may remain on a surface of a wiring or an insulating layer.

The transformed photoresist residue may include, e.g., a strong carbon-carbon bond, a carbon-silicon bond, a carbon-oxygen bond, or the like. The cleaning composition may include a fluorine-based compound capable of reacting with the bonds. The fluorine-based compound may react with silicon to form a silicon-fluorine bond, and may dissociate the transformed photoresist residue.

The fluorine-based compound may include an ionic bond of a hydrogen cation or an ammonium cation, and a fluorine anion. For example, the fluorine-based compound may include an ionic bond of a hydrogen cation, an ammonium cation or an ammonium cation including at least one hydrocarbon group, and a fluorine anion.

The ammonium cation may include one or more alkyl groups having 1 to 5 carbon atoms. For example, the ammonium cation may include a methyl group, an ethyl group, a propyl group, a butyl group, or the like.

In example embodiments, the ammonium cation may include 4 to 20 carbon atoms. In some embodiments, the ammonium cation may include 8 to 20 carbon atoms. For example, the ammonium cation may include tetramethylammonium, tetraethylammonium, tetrapropylammonium, tetrabutylammonium, tetrapentylammonium, or the like.

For example, the fluorine-based compound may include hydrofluoric acid (HF), ammonium fluoride, methylammonium fluoride, tetramethylammonium fluoride, tetraethylammonium fluoride, tetrapropylammonium fluoride, tetrabutylammonium fluoride, or the like. These may be used alone or in a combination of two or more therefrom.

In example embodiments, a content of the fluorine-based compound may be in a range from 0.005 wt % to 10 wt % based on a total weight of the composition. In some embodiments, the content of the fluorine-based compound may be in a range from 0.01 wt % to 10 wt % based on the total weight of the composition.

In the above range, the transformed photoresist residue may be rapidly removed without damaging a silicon-based layer (e.g., SiO₂, SiN, etc.).

The composition includes the organic acid salt compound. The organic acid salt compound may react with carbon components of the transformed photoresist residue to form a complex, thereby removing the transformed photoresist residue. Further, the organic acid salt compound may prevent etching of the silicon-based layer.

In example embodiments, the organic acid salt compound may include an ionic bond between an ammonium-based cation and an organic acid-derived anion. The ammonium-based cation may be the same as that described in the fluorine-based compound.

The organic acid-derived anion may include one or more carboxyl anion moiety where a hydrogen atom is removed from a carboxyl group of an organic acid in a molecule.

For example, the organic acid may include formic acid, acetic acid, propionic acid, butyric acid, palmitic acid, stearic acid, oleic acid, oxalic acid, malonic acid, succinic acid, tartaric acid, maleic acid, glycolic acid, glutaric acid, adipic acid, sulfosuccinic acid, valeric acid, caproic acid, caprylic acid, capric acid, lauric acid, myristic acid, lactic acid, malic acid, citric acid, benzoic acid, salicylic acid, paratoluenesulfonic acid, naphthoic acid, nicotinic acid, toluic acid, anisic acid, cumic acid, phthalic acid, or the like.

In an embodiment, the organic acid may include acetic acid, lactic acid, oxalic acid, maleic acid, tartaric acid, citric acid, or the like. These may be used alone or in a combination of two or more therefrom.

In example embodiments, a content of the organic acid salt compound may be in a range from 0.01 wt % to 10 wt % based on the total weight of the composition. In some embodiments, the content of the organic acid salt compound may be in a range from 1 wt % to 10 wt % based on the total weight of the composition.

In the above range, the transformed photoresist residue may be more effectively removed, and surface adsorption of the organic acid salt compound may be prevented.

The cleaning composition includes an inorganic acid compound. Even using a small amount of the strongly acidic inorganic acid compound, a pH of the cleaning composition may be adjusted to 5 or less.

In example embodiments, the inorganic acid compound may include a compound having a redox potential of 650 mV or less, or a salt thereof. For example, the inorganic acid compound may include hydrochloric acid, phosphoric acid, sulfuric acid, boric acid, or a salt thereof.

In example embodiments, the inorganic acid compound may not include a compound having a redox potential exceeding 650 mV. For example, the inorganic acid compound may not include one or more of nitric acid, hydrobromic acid, iodic acid, metaperiodic acid, orthoperiodic acid, iodous acid, hypoiodous acid, hydroiodic acid, chloric acid, perchloric acid, chlorous acid, hypochlorous acid, etc., or a salt thereof. For example, the inorganic acid compound may not include any of the above-mentioned compounds.

In example embodiments, the inorganic acid compound may not include nitric acid. Accordingly, damages to a metal layer or a wiring caused by nitric acid may be avoided.

The redox potential may be measured by immersing a redox potential electrode in a measuring solution containing the inorganic acid compound while stirring the measuring solution.

The pH of the cleaning composition may be in a range from 0.5 to 4. In some embodiments, the pH of the cleaning composition may be in a range from 1 to 3, or from 1.2 to 2. In example embodiments, a type and a content of the inorganic acid compound may be adjusted in consideration of the pH of the cleaning composition as described above.

In the above range, the cleaning composition may become relatively acidic, and the transformed photoresist residue may be more rapidly removed by the organic acid salt compound and the fluorine-based compound in an acidic atmosphere.

If the pH of the cleaning composition is less than 1, the content of the inorganic acid compound may be excessive to cause the inorganic acid compound to adsorb to a surface. Accordingly, the transformed photoresist residue may not be sufficiently removed.

If the pH of the cleaning composition exceeds 4, the cleaning composition may not form a sufficiently acidic atmosphere. Accordingly, a chemical reaction between the organic acid salt compound and the fluorine-based compound, and the transformed photoresist residue may not occur.

The cleaning composition includes water. Water may be a major component of the composition, and may be present in an excessive amount relative to the total weight of the composition. For example, a content of water may be at least 50 wt % based on the total weight of the composition.

In example embodiments, the content of water may be at least 60 wt %, at least 70 wt %, or at least 80 wt % based on the total weight of the composition. In an embodiment, water may be included in a remaining amount of the composition, excluding the contents of the fluorine-based compound, the organic acid salt compound, and the inorganic acid compound. The remaining amount may refer to a variable amount that is adjusted according to inclusion of other additional components.

In example embodiments, the cleaning composition may not include a basic compound. The basic compound may neutralize the inorganic acid compound, thereby increasing the pH and reducing the cleaning power of the cleaning composition.

In some embodiments, the cleaning composition may not include an amine compound, an ammonium hydroxide compound and/or a metal hydroxide. For example, the amine compound may include a primary to tertiary amine that may be dissolved in water to have a pH of 7 or higher. For example, the ammonium hydroxide compound may include an ionic bond between an ammonium cation and a hydroxide ion (OH⁻). For example, the metal hydroxide may include an alkali metal hydroxide.

For example, the basic compound may include an amine compound including a primary to tertiary aliphatic amine, an alicyclic amine, a heterocyclic amine, an aromatic amine, etc.; an ammonium hydroxide compound including ammonium hydroxide, trimethylammonium hydroxide, triethylammonium hydroxide, etc.; or a metal hydroxide including NaOH, KOH, Ca(OH)₂, Al(OH)₃, etc.

In some embodiments, the cleaning composition may not include an oxidizing agent. For example, the oxidizing agent may etch a metal wiring of the semiconductor device during a cleaning process, thereby degrading the quality of the semiconductor device.

In some embodiments, the cleaning composition may not include a peroxide compound. For example, the peroxide compound may include hydrogen peroxide, peroxymonosulfuric acid, peroxydisulfuric acid, or a salt thereof.

In some embodiments, the cleaning composition may not include an organic solvent. The organic solvent may inhibit the reaction between the fluorine-based compound and the transformed photoresist, and may reduce solubility of the fluorine-based compound, the organic acid salt compound and the inorganic acid compound.

For example, the organic solvent may include propylene glycol methyl ether (PGME), propylene glycol monomethyl ether acetate (PGMEA), tetrahydrofuran (THF), methanol, ethanol, isopropyl alcohol (IPA), methoxypropanol, dimethyl sulfoxide (DMSO), N-methylpyrrolidone (NMP), methyl ethyl ketone (MEK), acetone, hexane, methyl isobutyl ketone (MIBK), acrylonitrile, acetonitrile, ethyl acetate, phenol, benzene, toluene, xylene, etc.

In some embodiments, the cleaning composition may not include a surfactant. When performing a cleaning process using a cleaning composition including the surfactant, bubbles may be formed to reduce the cleaning power. For example, the surfactant may be an anionic surfactant such as sodium dodecyl sulfate (SDS), ammonium lauryl sulfate (ALS), sodium lauryl ethylene sulfate (SLES), linear alkylbenzene sulfonate (LAS), alpha-olefin sulfonate (AOS), alkyl sulfate (AS), alkyl ether sulfate (AES), sodium alkane sulfonate (SAS), etc.; a cationic surfactant such as alkyldimethylbenzyl chloride, tetradecyldimethylbenzylammonium chloride, hexadecyltrimethylammonium chloride, behenyltrimethylammonium chloride, alkylpropylenediamine acetate, octadecylamine acetate, tetradecylamine acetate, didecyldimethylammonium chloride, octadecyldimethylbenzylammonium chloride, etc.; decylphosphonic acid, dodecylphosphonic acid, tetradecylphosphonic acid, hexadecylphosphonic acid, bis(2-ethylhexyl)phosphate, octadecylphosphonic acid, perfluoroheptanoic acid, perfluorodecanoic acid, trifluorodecanoic acid, trifluoromethanesulfonic acid, phosphonoacetic acid, dodecylbenzenesulfonic acid, dodecylamine, dodecylphenoxypolyethoxyethanol, etc.

In an embodiment, the cleaning composition may substantially consist of the fluorine-based compound, the organic acid salt compound, the inorganic acid compound, and water. For example, the cleaning composition may not include any further components other than the fluorine-based compound, the organic acid salt compound, the inorganic acid compound and water. For example, a sum of the contents of the fluorine-based compound, the organic acid salt compound, the inorganic acid compound, and water based on the total weight of the cleaning composition may be 100 wt %.

According to embodiments, a method of fabricating a semiconductor device using the cleaning composition may be provided. The cleaning composition may be used in various processes for removing residual photoresist and, an application of the composition is not limited to embodiments as described below.

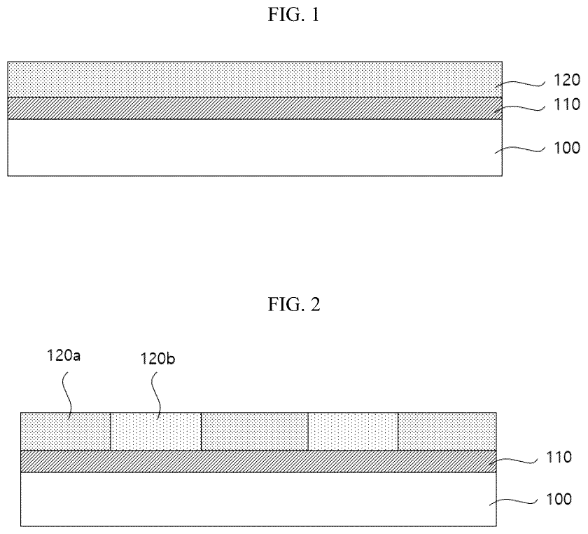

FIGS. 1 to 5 are schematic cross-sectional views illustrating a method of fabricating a semiconductor device according to embodiments.

Referring to FIG. 1, a photoresist layer 120 may be formed by coating a photoresist on a substrate 100.

The substrate 100 may include a semiconductor material such as single crystalline silicon or a single crystalline germanium, and may also include polysilicon.

An etching target layer 110 may be formed on the substrate 100. The photoresist layer 120 may be formed on the etching target layer 110.

The etching target layer 110 may include a metal layer for forming wirings, an insulating layer for insulating the wirings, and/or a semiconductor layer.

In some embodiments, a soft baking process may be performed after forming the photoresist layer 120. Accordingly, an organic solvent included in the photoresist layer 120 may be evaporated.

Referring to FIG. 2, the photoresist layer 120 may be divided into a non-exposed portion 120b and an exposed portion 120a. An exposure process may be performed using a light source (e.g., an EUV light source) and an exposure mask.

A light (e.g., EUV) passing through an opening of the exposure mask may be irradiated to the photoresist layer 120. Accordingly, the photoresist layer 120 may be divided into the non-exposed portion 120b that may not overlap the opening, and an exposed portion 120a overlapping the opening.

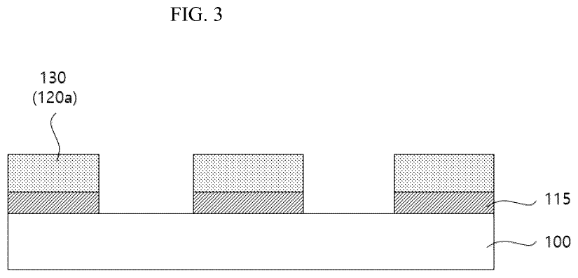

Referring to FIG. 3, the exposed portion 120a or the non-exposed portion 120b may be removed by a developing process using a developer solution to form a photoresist pattern 130 on the substrate 100 or the etching target layer 110. The developer solution may be an aqueous tetramethylammonium hydroxide (TMAH) solution.

As illustrated in FIG. 3, when the photoresist layer 120 includes a negative photoresist, the non-exposed portion 120b may be removed by the developing process, and the photoresist pattern 130 may be defined by the remaining exposed portion 120a.

Alternatively, when the photoresist layer 120 includes a positive photoresist, the exposed portion 120a may be removed by the developing process, and the photoresist pattern 130 may be defined by the remaining non-exposed portion 120b.

In some embodiments, a post-baking process may be further performed after the exposure process or after the developing process.

The etching target layer 110 may be etched using the photoresist pattern 130 as an etching mask. A target pattern 115 may be formed from the etching target layer 110 by the etching. The target pattern 115 may be a fine wiring, an insulating pattern, or a semiconductor pattern of a semiconductor device. The etching may include a dry etching or a wet etching.

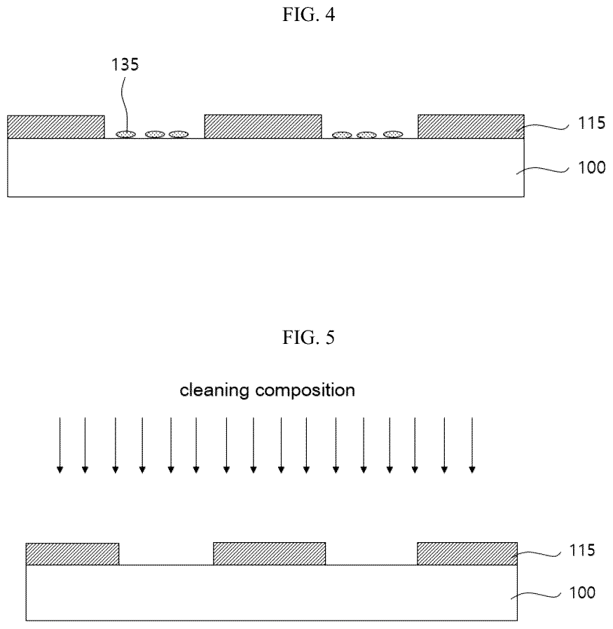

Referring to FIG. 4, the photoresist pattern 130 may be removed by, e.g., an ashing process.

In the ashing process, the photoresist pattern 130 may be substantially combusted and removed. For example, the ashing may include a plasma ashing, and may be performed by injecting a reactive gas such as oxygen.

The ashing process may be performed at high temperature, and thus a portion of the photoresist pattern 130 may react with a semiconductor material of the substrate 100 by a high-temperature energy to form a transformed residue 135.

Referring to FIG. 5, the transformed residue 135 may be removed using the cleaning composition according to the above-described embodiments. Accordingly, a highly reliable semiconductor device may be provided without damages to the target pattern 115 of the semiconductor device, e.g., a metal wiring, a silicon-containing layer, or the like, formed on the substrate 100.

For example, the cleaning process using the above cleaning composition may be performed through immersing and/or spraying in a batch type etching device or a single type etching device.

Hereinafter, experimental examples are proposed to more concretely describe the present invention. However, the following examples are only given for illustrating the present invention and those skilled in the related art will obviously understand that various alterations and modifications are possible within the scope and spirit of the present invention. Such alterations and modifications are duly included in the appended claims.

### EXAMPLES AND COMPARATIVE EXAMPLES

As shown in Tables 1 and 2 below, cleaning compositions were prepared using the types and contents of the fluorine-based compound, the organic acid salt compound and the inorganic acid compound, and using a remaining amount of water. The content of each component is expressed in wt % based on a total weight of the composition, and Tables 1 and 2 show pH of each cleaning composition.

TABLE 1

| | fluorine-based compound | | organic acid salt compound | | inorganic acid compound | | |
|---|---|---|---|---|---|---|---|
| | | content | | content | | content | |
| | type | (wt %) | type | (wt %) | type | (wt %) | pH |
| Example 1 | A-5 | 0.0005 | B-7 | 2.5 | C-1 | 3 | 1.4 |
| Example 2 | A-5 | 0.005 | B-7 | 2.5 | C-1 | 3 | 1.4 |
| Example 3 | A-5 | 0.01 | B-7 | 2.5 | C-1 | 3 | 1.4 |
| Example 4 | A-5 | 0.1 | B-7 | 2.5 | C-1 | 3 | 1.4 |
| Example 5 | A-5 | 2.5 | B-7 | 2.5 | C-1 | 3 | 1.4 |
| Example 6 | A-5 | 10 | B-7 | 2.5 | C-1 | 3 | 1.4 |
| Example 7 | A-5 | 15 | B-7 | 2.5 | C-1 | 3 | 1.4 |
| Example 8 | A-5 | 2.5 | B-7 | 0.005 | C-1 | 3 | 1.4 |
| Example 9 | A-5 | 2.5 | B-7 | 0.01 | C-1 | 3 | 1.4 |
| Example 10 | A-5 | 2.5 | B-7 | 2.5 | C-1 | 3 | 1.4 |
| Example 11 | A-5 | 2.5 | B-7 | 10 | C-1 | 3 | 1.4 |
| Example 12 | A-5 | 2.5 | B-7 | 15 | C-1 | 3 | 1.4 |
| Example 13 | A-5 | 2.5 | B-7 | 2.5 | C-1 | 0.001 | 4.5 |
| Example 14 | A-5 | 2.5 | B-7 | 2.5 | C-1 | 0.005 | 3.5 |
| Example 15 | A-5 | 2.5 | B-7 | 2.5 | C-1 | 0.01 | 3 |
| Example 16 | A-5 | 2.5 | B-7 | 2.5 | C-1 | 3 | 1.4 |
| Example 17 | A-5 | 2.5 | B-7 | 2.5 | C-1 | 7 | 1.1 |
| Example 18 | A-5 | 2.5 | B-7 | 2.5 | C-1 | 10 | 0.9 |
| Example 19 | A-5 | 2.5 | B-7 | 2.5 | C-1 | 20 | 0.1 |
| Example 20 | A-2 | 0.0005 | B-7 | 2.5 | C-1 | 3 | 1.4 |
| Example 21 | A-2 | 0.005 | B-7 | 2.5 | C-1 | 3 | 1.4 |
| Example 22 | A-2 | 0.01 | B-7 | 2.5 | C-1 | 3 | 1.4 |
| Example 23 | A-2 | 0.1 | B-7 | 2.5 | C-1 | 3 | 1.4 |
| Example 24 | A-2 | 2.5 | B-7 | 2.5 | C-1 | 3 | 1.4 |
| Example 25 | A-2 | 10 | B-7 | 2.5 | C-1 | 3 | 1.4 |
| Example 26 | A-2 | 15 | B-7 | 2.5 | C-1 | 3 | 1.4 |
| Example 27 | A-2 | 2.5 | B-7 | 0.005 | C-1 | 3 | 1.4 |
| Example 28 | A-2 | 2.5 | B-7 | 0.01 | C-1 | 3 | 1.4 |
| Example 29 | A-2 | 2.5 | B-7 | 2.5 | C-1 | 3 | 1.4 |
| Example 30 | A-2 | 2.5 | B-7 | 10 | C-1 | 3 | 1.4 |
| Example 31 | A-2 | 2.5 | B-7 | 15 | C-1 | 3 | 1.4 |
| Example 32 | A-2 | 2.5 | B-7 | 2.5 | C-1 | 0.001 | 4.5 |
| Example 33 | A-2 | 2.5 | B-7 | 2.5 | C-1 | 0.005 | 3.5 |
| Example 34 | A-2 | 2.5 | B-7 | 2.5 | C-1 | 0.01 | 3 |
| Example 35 | A-2 | 2.5 | B-7 | 2.5 | C-1 | 3 | 1.4 |
| Example 36 | A-2 | 2.5 | B-7 | 2.5 | C-1 | 7 | 1.1 |
| Example 37 | A-2 | 2.5 | B-7 | 2.5 | C-1 | 10 | 0.9 |
| Example 38 | A-2 | 2.5 | B-7 | 2.5 | C-1 | 20 | 0.1 |
| Example 39 | A-3 | 2.5 | B-7 | 2.5 | C-1 | 3 | 1.4 |
| Example 40 | A-4 | 2.5 | B-7 | 2.5 | C-1 | 3 | 1.4 |
| Example 41 | A-1 | 2.5 | B-7 | 2.5 | C-1 | 3 | 1.4 |
| Example 42 | A-6 | 2.5 | B-7 | 2.5 | C-1 | 3 | 1.4 |
| Example 43 | A-7 | 2.5 | B-7 | 2.5 | C-1 | 3 | 1.4 |
| Example 44 | A-8 | 2.5 | B-7 | 2.5 | C-1 | 3 | 1.4 |
| Example 45 | A-2 | 2.5 | B-2 | 2.5 | C-1 | 3 | 1.4 |
| Example 46 | A-2 | 2.5 | B-3 | 2.5 | C-1 | 3 | 1.4 |
| Example 47 | A-2 | 2.5 | B-4 | 2.5 | C-1 | 3 | 1.4 |
| Example 48 | A-2 | 2.5 | B-5 | 2.5 | C-1 | 3 | 1.4 |
| Example 49 | A-2 | 2.5 | B-6 | 2.5 | C-1 | 3.5 | 1.4 |
| Example 50 | A-2 | 2.5 | B-1 | 2.5 | C-1 | 3 | 1.4 |
| Example 51 | A-2 | 2.5 | B-7 | 2.5 | C-2 | 3 | 1.4 |
| Example 52 | A-2 | 2.5 | B-7 | 2.5 | C-3 | 3 | 1.4 |
| Example 53 | A-2 | 2.5 | B-7 | 2.5 | C-4 | 3 | 1.4 |

TABLE 2

| | fluorine-based compound | | organic acid salt compound | | inorganic acid compound | | other compound | | |
|---|---|---|---|---|---|---|---|---|---|
| | | content | | content | | content | | content | |
| | type | (wt %) | type | (wt %) | type | (wt %) | type | (wt %) | pH |
| Comparative | — | — | B-1 | 2.5 | C-1 | 3 | — | — | 1.4 |
| Example 1 | | | | | | | | | |
| Comparative | A-2 | 2.5 | — | — | C-1 | 3 | — | — | 1.4 |
| Example 2 | | | | | | | | | |
| Comparative | A-2 | 2.5 | B-1 | 2.5 | — | — | — | — | 6.5 |
| Example 3 | | | | | | | | | |
| Comparative | — | — | B-1 | 2.5 | C-1 | 3 | D-1 | 10 | 1.4 |
| Example 4 | | | | | | | | | |
| Comparative | A-2 | 2.5 | — | — | C-1 | 3 | D-2 | 10 | 1.4 |
| Example 5 | | | | | | | | | |
| Comparative | — | — | B-1 | 2.5 | C-1 | 3 | D-3 | 10 | 1.4 |
| Example 6 | | | | | | | | | |
| Comparative | A-2 | 2.5 | — | — | C-1 | 3 | D-4 | 10 | 1.4 |
| Example 7 | | | | | | | | | |
| Comparative | — | — | B-1 | 2.5 | C-1 | 3 | D-5 | 10 | 1.4 |
| Example 8 | | | | | | | | | |
| Comparative | A-2 | 2.5 | — | — | C-1 | 3 | D-6 | 10 | 1.4 |
| Example 9 | | | | | | | | | |
| Comparative | — | — | B-1 | 2.5 | C-1 | 3 | E-1 | 5 | 1.4 |
| Example 10 | | | | | | | | | |
| Comparative | A-2 | 2.5 | — | — | C-1 | 3 | F-1 | 10 | 13 |
| Example 11 | | | | | | | | | |
| Comparative | — | — | B-1 | 2.5 | C-1 | 3 | F-2 | 10 | 13 |
| Example 12 | | | | | | | | | |
| Comparative | A-2 | 2.5 | B-1 | 2.5 | — | — | F-3 | 10 | 11 |
| Example 13 | | | | | | | | | |
| Comparative | — | — | B-1 | 2.5 | C-1 | 3 | G-1 | 0.1 | 1.4 |
| Example 14 | | | | | | | | | |
| Comparative | A-2 | 2.5 | — | — | C-1 | 3.5 | G-2 | 0.1 | 1.4 |
| Example 15 | | | | | | | | | |
| Comparative | A-2 | 2.5 | B-1 | 2.5 | — | — | G-3 | 0.1 | 1.4 |
| Example 16 | | | | | | | | | |
| Comparative | — | — | B-1 | 2.5 | C-1 | 3.5 | G-4 | 0.1 | 1.4 |
| Example 17 | | | | | | | | | |
| Comparative | A-2 | 2.5 | — | — | C-1 | 3.5 | G-5 | 0.1 | 1.4 |
| Example 18 | | | | | | | | | |
| Comparative | A-2 | 2.5 | B-1 | 2.5 | C-1 | 3.5 | D-1 | 40 | 1.0 |
| Example 19 | | | | | | | | | |

A-6: tetrapentylammonium fluoride (TPentylAF)
A-7: ethyltrimethylammonium fluoride (ETMAF)
A-8: diethyldimethyltylammonium fluoride (DEDMAF)
B-1: tetramethylammonium (TMA) acetate
B-2: TMA formate
B-3: TMA lactate
B-4: TMA oxalate
B-5: TMA malate
B-6: TMA tartrate
B-7: TMA citrate
C-1: phosphoric acid
C-2: sulfuric acid
C-3: hydrochloric acid
C-4: nitric acid
D-1: propylene glycol monomethyl ether acetate (PGMEA)
D-2: propylene glycol methyl ether (PGME)
D-3: tetrahydrofuran (THF)
D-4: isopropyl alcohol (IPA)
D-5: acetone
D-6: dimethyl sulfoxide (DMSO)
E-1: hydrogen peroxide (H₂O₂)
F-1: sodium hydroxide (NaOH)
F-2: tetramethylammonium hydroxide (TMAH)
F-3: ammonium hydroxide (NH₄OH)
G-1: sodium dodecyl sulfate
G-2: hexadecylphosphonic acid
G-3: perfluorodecanoic acid
G-4: 2-(p-dodecylphenoxyethoxy)-ethoxyethanol
G-5: hexadecyltrimethylammonium chloride

### Experimental Example

Properties of the cleaning compositions of Examples and Comparative Examples were evaluated by the following methods, and the results are shown in Tables 3 and 4.

### (1) Evaluation on Cleaning Transformed Photoresist Residue

Transformed photoresist residues was formed on a silicon wafer and cut into 1.5 cm×1.5 cm to prepare samples. An initial residue amount was calculated using a scanning electron microscope (SEM) as a pixel area of the transformed photoresist residue on a surface of the sample.

The samples were immersed in a beaker containing the cleaning compositions of Examples and Comparative Examples at 25° C. and 400 rpm for 100 seconds. Thereafter, the samples were taken out, rinsed with water, and air-dried.

The transformed photoresist residue remaining on the sample surface after the treatment was analyzed using an SEM, and then an amount of the residue after the treatment was calculated based on a pixel area.

A ratio of the residue after the treatment relative to an initial residue was calculated and evaluated according to the following criteria.

### <Evaluation Criteria>

Level 5: about 80% to 100% of initial value
Level 4: about 60% to 80% of initial value
Level 3: about 40% to 60% of initial value
Level 2: about 20% to 40% of initial value
Level 1: about 0% to 20% of initial value

### (2) Evaluation on SiO₂ Etching Rate

A silicon wafer on which 5,000 Å of SiO₂ was deposited was cut into a size of 1.5 cm×1.5 cm to prepare samples. The samples were immersed in a beaker containing the cleaning compositions of Examples and Comparative Examples at 25° C. and 400 rpm for 600 seconds. Thereafter, the samples were taken out, rinsed with water, and air-dried.

A thickness of the SiO₂ layer of the treated samples was measured using an ellipsometer. An etching rate of the SiO₂ layer was calculated using a change in the layer thickness and evaluated according to the following criteria.

### <Evaluation Criteria>

O: SiO₂ layer etching rate of 1 Å/min or less
Δ: SiO₂ layer etching rate of greater than 1 Å/min, and 10 Å/min or less
X: SiO₂ layer etching rate of greater than 10 Å/min

### (3) Evaluation on SiNx Etching Rate

A silicon wafer on which 1,000 Å of SiNx was deposited was cut into a size of 1.5 cm×1.5 cm to prepare samples. The samples were immersed in a beaker containing the cleaning compositions of Examples and Comparative Examples at 25° C. and 400 rpm for 600 seconds. Thereafter, the samples were taken out, rinsed with water, and air-dried.

A thickness of the SiNx layer of the treated samples was measured using an ellipsometer. An etching rate of the SiNx layer was calculated using a change in the layer thickness and evaluated according to the following criteria.

### <Evaluation Criteria>

O: SiNx layer etching rate of 1 Å/min or less
Δ: SiNx layer etching rate of greater than 1 Å/min, and 10 Å/min or less
X: SiNx layer etching rate of greater than 10 Å/min

### (4) Evaluation on Mo Etching Rate

A silicon wafer on which 200 Å of Mo was deposited was cut into a size of 3.0 cm×3.0 cm to prepare samples. The samples were immersed in a beaker containing the cleaning compositions of Examples and Comparative Examples at 25° C. and 400 rpm for 600 seconds. Thereafter, the samples were taken out, rinsed with water, and air-dried.

A thickness of the Mo layer of the treated samples was measured using an X-ray fluorescence spectrometer (XRF). An etching rate of the Mo layer was calculated using a change in the layer thickness and evaluated according to the following criteria.

### <Evaluation Criteria>

O: Mo layer etching rate of 1 Å/min or less
Δ: Mo layer etching rate of greater than 1 Å/min, and 10 Å/min or less
X: Mo layer etching rate of greater than 10 Å/min

### (5) Evaluation on W Etching Rate

A silicon wafer on which 200 Å of W was deposited was cut into a size of 3.0 cm×3.0 cm to prepare samples. The samples were immersed in a beaker containing the cleaning compositions of Examples and Comparative Examples at 25° C. and 400 rpm for 600 seconds. Thereafter, the samples were taken out, rinsed with water, and air-dried.

A thickness of the W layer of the treated samples was measured using an X-ray fluorescence spectrometer (XRF). An etching rate of the W layer was calculated using a change in the layer thickness and evaluated according to the following criteria.

### <Evaluation Criteria>

O: W layer etching rate of 1 Å/min or less
Δ: W layer etching rate of greater than 1 Å/min, and 10 Å/min or less
X: W layer etching rate of greater than 10 Å/min

### (6) Evaluation on Ru Etching Rate

A silicon wafer on which 100 Å of Ru was deposited was cut into a size of 3.0 cm×3.0 cm to prepare samples. The samples were immersed in a beaker containing the cleaning compositions of Examples and Comparative Examples at 25° C. and 400 rpm for 600 seconds. Thereafter, the samples were taken out, rinsed with water, and air-dried.

A thickness of the Ru layer of the treated samples was measured using an X-ray fluorescence spectrometer (XRF). An etching rate of the Ru layer was calculated using a change in the layer thickness and evaluated according to the following criteria.

### <Evaluation Criteria>

O: Ru layer etching rate of 1 Å/min or less
Δ: Ru layer etching rate of greater than 1 Å/min, and 10 Å/min or less
X: Ru layer etching rate of greater than 10 Å/min

TABLE 3

| | level of residue | evaluation on anti-corrosive property | | | | |
|---|---|---|---|---|---|---|
| | after treatment | Mo | W | Ru | SiO₂ | SiNₓ |
| Example 1 | 3 | ◯ | ◯ | ◯ | ◯ | ◯ |
| Example 2 | 1 | ◯ | ◯ | ◯ | ◯ | ◯ |
| Example 3 | 1 | ◯ | ◯ | ◯ | ◯ | ◯ |
| Example 4 | 1 | ◯ | ◯ | ◯ | ◯ | ◯ |
| Example 5 | 1 | ◯ | ◯ | ◯ | ◯ | ◯ |
| Example 6 | 1 | ◯ | ◯ | ◯ | ◯ | ◯ |
| Example 7 | 1 | ◯ | ◯ | ◯ | X | X |
| Example 8 | 2 | ◯ | ◯ | ◯ | ◯ | ◯ |
| Example 9 | 1 | ◯ | ◯ | ◯ | ◯ | ◯ |
| Example 10 | 1 | ◯ | ◯ | ◯ | ◯ | ◯ |
| Example 11 | 1 | ◯ | ◯ | ◯ | ◯ | ◯ |
| Example 12 | 2 | ◯ | ◯ | ◯ | ◯ | ◯ |
| Example 13 | 3 | ◯ | ◯ | ◯ | Δ | Δ |
| Example 14 | 1 | ◯ | ◯ | ◯ | ◯ | ◯ |
| Example 15 | 1 | ◯ | ◯ | ◯ | ◯ | ◯ |
| Example 16 | 1 | ◯ | ◯ | ◯ | ◯ | ◯ |
| Example 17 | 1 | ◯ | ◯ | ◯ | ◯ | ◯ |
| Example 18 | 1 | ◯ | ◯ | ◯ | ◯ | ◯ |
| Example 19 | 1 | ◯ | ◯ | ◯ | Δ | Δ |
| Example 20 | 3 | ◯ | ◯ | ◯ | ◯ | ◯ |
| Example 21 | 1 | ◯ | ◯ | ◯ | ◯ | ◯ |
| Example 22 | 1 | ◯ | ◯ | ◯ | ◯ | ◯ |
| Example 23 | 1 | ◯ | ◯ | ◯ | ◯ | ◯ |
| Example 24 | 1 | ◯ | ◯ | ◯ | ◯ | ◯ |
| Example 25 | 1 | ◯ | ◯ | ◯ | ◯ | ◯ |
| Example 26 | 1 | ◯ | ◯ | ◯ | X | X |
| Example 27 | 2 | ◯ | ◯ | ◯ | ◯ | ◯ |
| Example 28 | 1 | ◯ | ◯ | ◯ | ◯ | ◯ |
| Example 29 | 1 | ◯ | ◯ | ◯ | ◯ | ◯ |
| Example 30 | 1 | ◯ | ◯ | ◯ | ◯ | ◯ |
| Example 31 | 2 | ◯ | ◯ | ◯ | ◯ | ◯ |
| Example 32 | 3 | ◯ | ◯ | ◯ | Δ | Δ |
| Example 33 | 1 | ◯ | ◯ | ◯ | ◯ | ◯ |
| Example 34 | 1 | ◯ | ◯ | ◯ | ◯ | ◯ |
| Example 35 | 1 | ◯ | ◯ | ◯ | ◯ | ◯ |
| Example 36 | 1 | ◯ | ◯ | ◯ | ◯ | ◯ |
| Example 37 | 1 | ◯ | ◯ | ◯ | ◯ | ◯ |
| Example 38 | 1 | ◯ | ◯ | ◯ | Δ | Δ |
| Example 39 | 1 | ◯ | ◯ | ◯ | ◯ | ◯ |
| Example 40 | 1 | ◯ | ◯ | ◯ | ◯ | ◯ |
| Example 41 | 1 | ◯ | ◯ | ◯ | ◯ | ◯ |
| Example 42 | 1 | ◯ | ◯ | ◯ | ◯ | ◯ |
| Example 43 | 1 | ◯ | ◯ | ◯ | ◯ | ◯ |
| Example 44 | 1 | ◯ | ◯ | ◯ | ◯ | ◯ |
| Example 45 | 1 | ◯ | ◯ | ◯ | ◯ | ◯ |
| Example 46 | 1 | ◯ | ◯ | ◯ | ◯ | ◯ |
| Example 47 | 1 | ◯ | ◯ | ◯ | ◯ | ◯ |
| Example 48 | 1 | ◯ | ◯ | ◯ | ◯ | ◯ |
| Example 49 | 1 | ◯ | ◯ | ◯ | ◯ | ◯ |
| Example 50 | 1 | ◯ | ◯ | ◯ | ◯ | ◯ |
| Example 51 | 1 | ◯ | ◯ | ◯ | ◯ | ◯ |
| Example 52 | 1 | ◯ | ◯ | ◯ | ◯ | ◯ |
| Example 53 | 2 | Δ | Δ | Δ | ◯ | ◯ |

TABLE 4

| | level of residue | evaluation on anti-corrosive property | | | | |
|---|---|---|---|---|---|---|
| | after treatment | Mo | W | Ru | SiO₂ | SINₓ |
| Comparative | 5 | ◯ | ◯ | ◯ | ◯ | ◯ |
| Example 1 | | | | | | |
| Comparative | 4 | ◯ | ◯ | ◯ | ◯ | ◯ |
| Example 2 | | | | | | |
| Comparative | 5 | ◯ | ◯ | ◯ | ◯ | ◯ |
| Example 3 | | | | | | |
| Comparative | 5 | ◯ | ◯ | ◯ | ◯ | ◯ |
| Example 4 | | | | | | |
| Comparative | 4 | ◯ | ◯ | ◯ | ◯ | ◯ |
| Example 5 | | | | | | |
| Comparative | 5 | ◯ | ◯ | ◯ | ◯ | ◯ |
| Example 6 | | | | | | |
| Comparative | 4 | ◯ | ◯ | ◯ | ◯ | ◯ |
| Example 7 | | | | | | |
| Comparative | 5 | ◯ | ◯ | ◯ | ◯ | ◯ |
| Example 8 | | | | | | |
| Comparative | 4 | ◯ | ◯ | ◯ | ◯ | ◯ |
| Example 9 | | | | | | |
| Comparative | 5 | X | X | X | ◯ | ◯ |
| Example 10 | | | | | | |
| Comparative | 5 | ◯ | ◯ | ◯ | X | X |
| Example 11 | | | | | | |
| Comparative | 5 | ◯ | ◯ | ◯ | X | X |
| Example 12 | | | | | | |
| Comparative | 5 | ◯ | ◯ | ◯ | ◯ | ◯ |
| Example 13 | | | | | | |
| Comparative | 5 | ◯ | ◯ | ◯ | ◯ | ◯ |
| Example 14 | | | | | | |
| Comparative | 4 | ◯ | ◯ | ◯ | ◯ | ◯ |
| Example 15 | | | | | | |
| Comparative | 5 | ◯ | ◯ | ◯ | ◯ | ◯ |
| Example 16 | | | | | | |
| Comparative | 5 | ◯ | ◯ | ◯ | ◯ | ◯ |
| Example 17 | | | | | | |
| Comparative | 4 | ◯ | ◯ | ◯ | ◯ | ◯ |
| Example 18 | | | | | | |
| Comparative | 5 | ◯ | ◯ | ◯ | ◯ | ◯ |
| Example 19 | | | | | | |

Referring to Table 3, the cleaning compositions of Examples which included the fluorine-based compound, the organic acid salt compound, the inorganic acid compounds, and an excess amount of water, and had a pH in a range from 0.5 to 4 provided high corrosion resistance with respect to metals such as Mo, W and Ru, and the silicon-based layer such as SiO₂ and SiNx, and provided high cleaning power with respect to the transformed photoresist residues.

In Example 53 where nitric acid was used as the inorganic acid compound, the etching rate of the metals including Mo, W and Ru was slightly increased compared to those from other Examples.

Referring to Table 4, the cleaning compositions of Comparative Examples which did not contain the fluorine compound, the organic acid salt compound or the inorganic acid compound provided degraded cleaning power with respect to the transformed photoresist residues.

Particularly, the cleaning compositions of Comparative Example 6 and Comparative Examples 11 to 13 showed excessively high pHs, resulting in reduced cleaning power the respect to the transformed photoresist residues.

Additionally, the cleaning composition of Comparative Example 19 contained an excessive amount of an organic solvent to have reduced cleaning power with respect to the transformed photoresist residue.

The above descriptions are merely example embodiments of application and principles of the present disclosure, and other elements may be included without departing from the scope of the present invention.

What is claimed is:

1. A cleaning composition comprising:
a fluorine-based compound;
an organic acid salt compound;
an inorganic acid compound; and
water,
wherein a content of water is at least 50 wt % based on a total weight of the composition, and the cleaning composition has a pH of 0.5 to 4.

2. The cleaning composition of claim 1, wherein the cleaning composition has a pH of 1 to 3.

3. The cleaning composition of claim 1, wherein the fluorine-based compound includes an ionic bond between a hydrogen cation or an ammonium cation, and a fluorine anion.

4. The cleaning composition of claim 3, wherein the ammonium cation contains 4 to 20 carbon atoms.

5. The cleaning composition of claim 1, wherein a content of the fluorine-based compound is in a range from 0.005 wt % to 10 wt % based on the total weight of the cleaning composition.

6. The cleaning composition of claim 1, wherein the organic acid salt compound includes an ionic bond between an ammonium cation and an organic acid-derived anion.

7. The cleaning composition of claim 6, wherein the organic acid includes at least one selected from the group consisting of formic acid, acetic acid, propionic acid, butyric acid, palmitic acid, stearic acid, oleic acid, oxalic acid, malonic acid, succinic acid, tartaric acid, maleic acid, glycolic acid, glutaric acid, adipic acid, sulfosuccinic acid, valeric acid, caproic acid, caprylic acid, capric acid, lauric acid, myristic acid, lactic acid, malic acid, citric acid, benzoic acid, salicylic acid, paratoluenesulfonic acid, naphthoic acid, nicotinic acid, toluic acid, anisic acid, cumic acid and phthalic acid.

8. The cleaning composition of claim 1, wherein a content of the organic acid salt compound is in a range from 0.01 wt % to 10 wt % based on the total weight of the composition.

9. The cleaning composition of claim 1, wherein the inorganic acid compound includes at least one selected from the group consisting of hydrochloric acid, phosphoric acid, sulfuric acid and boric acid.

10. The cleaning composition of claim 1, wherein the inorganic acid compound includes a compound having a redox potential of 650 mV or less, or a salt thereof.

11. The cleaning composition of claim 1, wherein a content of water is 80 wt % or more based on the total weight of the composition.

12. The cleaning composition of claim 1, wherein the cleaning composition does not include an amine compound, an ammonium hydroxide compound, a metal hydroxide, a peroxide compound, an organic solvent, or a surfactant.

13. A method for fabricating a semiconductor device, comprising:
forming a photoresist pattern on a substrate;
removing the photoresist pattern after an etching process using the photoresist pattern; and
cleaning a residue from the photoresist pattern using the cleaning composition according to claim 1.
